(19) United States
(12) Patent Application Publication
(10) Pub. No.: US 2015/0235978 A1
(43) Pub. Date: Aug. 20, 2015

(54) ELECTROLESS NICKEL BUMP OF DIE PAD AND MANUFACTURING METHOD THEREOF

(71) Applicant: AFLASH TECHNOLOGY CO., LTD., Taoyuan County (TW)

(72) Inventors: Ta-Lun Sung, Taoyuan County (TW); Kuei-Wu Chu, Taoyuan County (TW); Tung-Sheng Lai, Taoyuan County (TW)

(21) Appl. No.: 14/380,024

(22) PCT Filed: Jul. 5, 2012
(86) PCT No.: PCT/CN2012/000925

§ 371 Date: Feb. 24, 2015

(51) Int. Cl. H01L 23/00

(52) U.S. Cl. CPC H01L 24/14; H01L 24/11; H01L 2924/01028; H01L 2224/1401; H01L 2924/01047; H01L 2924/01079

(57) ABSTRACT

Electroless nickel bumps of die pads and a method thereof are disclosed. A protection layer is formed on the top surface and a surrounding sidewall of each electroless nickel bump in turn or at the same time by two separated processes or the same process. The two separated processes are selected from the group consisting of immersion gold and immersion silver. Thereby hardness of the top surface of the electroless nickel bump is improved and reduced. Moreover, easy oxidation of the surrounding sidewall of the electroless nickel bump and short circuit of the bump caused by electron migration can both be avoided.

### BACKGROUND OF THE INVENTION

The present invention relates to electroless nickel bumps of die pads and a manufacturing method thereof, especially to electroless nickel bumps of die pads and a manufacturing method thereof in which an outer protection layer is formed separatedly or simultaneously on a top surface and a surrounding sidewall of each electroless nickel bump by immersion gold or immersion silver process so as to improve and reduce hardness of the electroless nickel bump. Moreover, easy oxidation of the surrounding sidewall of the electroless nickel bump and short circuit of the bump caused by electron migration can both be avoided. Thus the manufacturing processes are simplified, the production cost is reduced and the quality is stable.

In the fields of link (such as bumps), package or manufacturing process of semiconductor chip or wafer, there are various techniques available now such as TW M397591, M352128, M412460, M412576, M410659, I306638, I320588, I255538, I459362, I253733, I273651, I288447, I295498, I241658, I259572, I472371, I24286, I269461, I329917, I282132, I328266, I284949, and the U.S. Pat. No. 8,030,767, U.S. Pat. No. 7,981,725, U.S. Pat. No. 7,969,003, U.S. Pat. No. 7,960,214, U.S. Pat. No. 7,847,414, U.S. Pat. No. 7,749,806, U.S. Pat. No. 7,651,886, U.S. Pat. No. 7,538,020, U.S. Pat. No. 7,750,467, U.S. Pat. No. 7,364,944, U.S. Pat. No. 7,019,406, U.S. Pat. No. 6,507,120, U.S. Pat. No. 7,999,387, U.S. Pat. No. 7,993,967, U.S. Pat. No. 7,868,470, U.S. Pat. No. 7,868,449, U.S. Pat. No. 7,972,902, U.S. Pat. No. 7,960,825, U.S. Pat. No. 7,952,187, U.S. Pat. No. 7,944,043, U.S. Pat. No. 7,934,313, U.S. Pat. No. 7,906,855, etc. These prior arts all have slight improvement. Thus compared with the crowded arts, the present invention has an inventive step even with just a little progress.

In conventional processes, a metal layer is formed on die pads by Under Bump Metallization (UBM) before formation of the bumps. Then the bumps are formed on the metal layer of the die pads by metal electroplating or printing of silver paste. Both the production cost and the manufacturing difficulty are higher. Moreover, the manufacturing processes are complicated and the yield rate is reduced. The formation of the bumps also needs more precious metal materials.

Furthermore, the bump made from silver paste has larger range of hardness. That means the hardness can be adjusted by heating conditions. However, the conventional electroless nickel bump has smaller hardness range. That means the surface hardness of the electroless nickel bump is larger and unable to be adjusted by heating conditions. This has negative effect on the following adhesion process.

In addition, the electroless nickel bump is easy to get oxidized without being covered by a sidewall protection layer. At the same time, short circuit occurs between the bumps due to electron migration. Although a part of prior arts such as TW M410659, US2011/0260300591, and TW M397591, etc., have revealed the structure or method for manufacturing the sidewall protection layer, these structure and methods are complicated. The production cost is unable to be reduced without simplifying the manufacturing processes. This also has negative effect on mass production. Generally, the electroless nickel bumps are conventionally produced without the photoresist covering. Although the electroless nickel bumps produced have the sidewall protection layers, the height of the electroless nickel bump is smaller (such as 2-10 μm) and the distance between two adjacent bumps is limited. Thus the bumps are unable to be produced delicately and the practical requirements of the product in the field are unable to be met.

There is room for improvement and a need to provide bumps with sidewall protection layers, produced by simple processes and reduced cost. The surface hardness of the bumps meets requirements of following adhesion process.

### SUMMARY OF THE INVENTION

Therefore it is a primary object of the present invention to provide electroless nickel bumps of die pads and a method thereof. Under the condition with photoresist coating, the bumps 30 with a certain height are formed on the surface of a catalyst layers on surface of the die pads respectively by electroless nickel plating. The bump is made from electroless nickel. Then use two separated manufacturing processes or the same manufacturing process selected from immersion gold and immersion silver process to form outer protection layers on a top surface and a surrounding sidewall of the bumps respectively or simultaneously so as to cover the exposed surface of the electroless nickel bumps completely. The outer protection layer includes at least one protection layer made from one of the materials selected from immersion gold or electroless silver. Thereby the hardness of the electroless nickel bump is improved and reduced. Moreover, the easily-oxidized problem of the surrounding sidewall of the electroless nickel bump and the short circuit problem caused by electron migration can also be solved. The manufacturing processes are simplified, the production cost is reduced and the quality of the product is stable.

In order to achieve the above object, electroless nickel bumps of die pads according to the present invention includes a die, a plurality of catalyst layers, a plurality of electroless nickel bumps, and a plurality of protection layers. The die consists of a surface, a plurality of die pads disposed on the surface, and a protection layer that is formed on the surface and having a plurality of openings. The die pad is exposed through the opening correspondingly. The catalyst layers are formed on the surface of the die pads respectively by under bump metallization (UBM) or zincating. The bumps with a certain height and made from electroless nickel are formed on the surface of the catalyst layers of the die pads by electroless nickel plating under the condition with photoresist coating. The protection layers are formed on a top surface and a surrounding sidewall of the bumps respectively or simultaneously by two separated manufacturing processes or the same manufacturing process selected from immersion gold and immersion silver process so as to cover the surface of the electroless nickel bumps completely. The protection layer includes at least one protection layer made from immersion gold (IG) or electroless silver (ES). Thereby the hardness of the electroless nickel bump is reduced. Moreover, oxidation of the surrounding sidewall of the electroless nickel bump and short circuit caused by electron migration can both be avoided. Therefore the manufacturing processes are simplified, the production cost is reduced and the quality of the product is stable.

A manufacturing method of electroless nickel bumps of die pads includes a plurality of steps as follows.

First, provide a die with a surface while a plurality of die pads is disposed on the surface and a first protection layer with a plurality of openings for exposure of the die pads correspondingly is formed on the surface.

Then form a photoresist layer on the first protection layer and pattern the photoresist layer so as to have a plurality of openings corresponding to each die pad and a part of the first protection layer surrounding the die pad.

Next form a catalyst layer on a surface of each die pad by a process selected from the group consisting of under bump metallization (UBM) and zincating.

Form an electroless nickel bump in each of the openings by electroless nickel plating.

Form a top surface protection layer on a top surface of each electroless nickel bump by a process selected from the group consisting of immersion gold and immersion silver under the condition with the photoresist layer. The top surface protection layer includes at least one protection layer made from a material selected from the group consisting of immersion gold (IG) and electroless silver (ES).

Remove the photoresist layer to expose the top surface protection layers, the electroless nickel bumps (the surrounding sidewall thereof) and a part of the first protection layers not beyond the bumps.

At last, form a sidewall protection layer on a surrounding sidewall of each electroless nickel bump by a process selected from the group of immersion gold and immersion silver. The sidewall surface protection layer includes at least one protection layer made from a material selected from the group consisting of immersion gold (IG) and electroless silver (ES).

In the above method, the plurality of top surface protection layers and sidewall protection layers are formed by two separated processes. The top surface protection layers are first formed on top surface of the electroless nickel bumps by a process selecting from the group consisting of immersion gold and immersion silver. Then a sidewall protection layer is formed on a surrounding sidewall of each electroless nickel bump by a process selecting from the group consisting of immersion gold and immersion silver.

Furthermore, another embodiment of a manufacturing method of electroless nickel bumps of die pads according to the present invention includes a plurality of steps as follows.

First, provide a die with a surface while a plurality of die pads is disposed on the surface and a first protection layer with a plurality of openings for exposure of the die pads correspondingly is formed on the surface.

Then form a photoresist layer on the first protection layer and pattern the photoresist layer so as to make the patterned photoresist layer have a plurality of openings corresponding to each die pad and a part of the first protection layer surrounding the die pad.

Next form a catalyst layer on a surface of each die pad by a process selected from the group consisting of under bump metallization (UBM) and zincating.

Form an electroless nickel bump in each of the openings by electroless nickel plating.

Remove the photoresist layer to expose the electroless nickel bumps, and a part of the first protection layers not beyond the bumps.

At last, form an outer protection layer on a top surface and a surrounding sidewall of each of the electroless nickel bumps respectively at the same time by a process selected from the group consisting of immersion gold and immersion silver while the outer protection layer includes at least one protection layer made from a material selected from the group consisting of immersion gold (IG) and electroless silver (ES).

In the method mentioned above, the outer protection layer is formed on the top surface of and the surrounding sidewall of each electroless nickel bump simultaneously by the same process selected from the group consisting of immersion gold and immersion silver.

### BRIEF DESCRIPTION OF THE DRAWINGS

FIG. 1 is a schematic drawing showing a cross section of an embodiment of electroless nickel bumps of die pads according to the present invention;

FIG. 2 is a schematic drawing showing a cross section of an embodiment of electroless nickel bumps of die pads according to the present invention;

FIG. 3 is a schematic drawing showing a cross section of an embodiment of electroless nickel bumps of die pads according to the present invention;

FIG. 4 is a schematic drawing showing a cross section of an embodiment of electroless nickel bumps of die pads according to the present invention;

FIG. 5A to FIG. 5G are schematic drawings showing cross sections of an embodiment of electroless nickel bumps of die pads formed by two separated processes during manufacturing processes according to the present invention;

FIG. 6A to FIG. 6F are schematic drawings showing cross sections of an embodiment of electroless nickel bumps of die pads formed by the same process at the same time during manufacturing processes according to the present invention.

### DETAILED DESCRIPTION OF THE PREFERRED EMBODIMENTS

Refer from FIG. 1 to FIG. 4, electroless nickel bumps of die pads 1 according to the present invention includes a die 10, a plurality of catalyst layers 20, a plurality of electroless nickel bumps 30, a plurality of top surface protection layers 40 and a plurality of sidewall protection layers 60.

The die 10 consists of a surface 11, a plurality of die pads 12 disposed on the surface 11 and a first protection layer 13 formed on the surface 11 and having a plurality of openings 14. The die pad 12 is exposed through the opening 14 correspondingly. The die 10 is generally produced by wafer fabrication factories. The die pad 12 layout on the surface is not limited. The layout can be designed into various arrays according to client's requirements. The first protection layer 13 is made from nitride.

The catalyst layers 20 are formed on the surface of the die pads respectively by under bump metallization (UBM) or zincating. The catalyst layer 20 is mainly used for connecting the die pads 12 and worked as deposition medium for following electroless metal deposition so as to form the electroless nickel bumps 30. In an embodiment of the present invention, the catalyst layer 20 made from zinc is produced by using 15-30% (w/w) aqueous solutions of zinc salts at 20-35 degrees Celsius for 10 seconds to 60 seconds.

The bumps 30 with a certain height are formed on the surface of the catalyst layers 20 on surface of the die pads 12 respectively by electroless nickel plating. Thus the bump 30 is called electroless nickel bump 30. In this embodiment, the thickness of the bump 30 is formed due to deposition of electroless nickel (electroless deposition of nickel) with photoresist coating. Thus the height of the bump 30 meets the design requirement. The nickel salts are used and nickel (II) phosphate is preferred. This is due to that nickel (II) phosphate has self-catalytic property so as to increase the thickness (height) of the electroless nickel bump 30. In this embodiment, the bump 30 made from electroless nickel is produced by using 4-6.5 g/L aqueous solutions of nickel salts at 75-100° C. for 30 minutes to 75 minutes.

The top surface protection layers 40 are formed on the top surfaces of the electroless nickel bumps 30 respectively. The top surface protection layer 40 includes at least one protection layer made from materials selected from the group consisting of immersion gold (IG) and electroless silver (ES). The top surface protection layer 40 is formed on top surface of each electroless bump 30 by immersion gold process or immersion silver process under the condition with or without a patterned photoresist layer 50. The sidewall protection layers 60 are arranged at surrounding sidewalls of the electroless nickel bumps 30 respectively. The sidewall protection layer 60 includes at least one protection layer made from materials selected from the group consisting of immersion gold (IG) and electroless silver (ES). The sidewall protection layer 60 is formed on the surrounding sidewall of each electroless bump 30 by immersion gold process or immersion silver process under the condition without a patterned photoresist layer 50. Both the top surface protection layer 40 on the top surfaces of each electroless nickel bump 30 and the sidewall protection layer 60 on the surrounding sidewall of each electroless nickel bump 30 are covered over the exposed surface of each electroless nickel bump 30 completely and tightly so as to form an integrated protection layer.

The top surface protection layer 40 and the sidewall protection layer 60 include following four different types of structure respectively. In practice, there are 16 possible combinations of the four bases taken two at a time. For example, the surface protection layer 40 with type one structure is paired with the sidewall protection layer 60 whose structure is type two, as shown in FIG. 1. The four different types of structure are as follows:

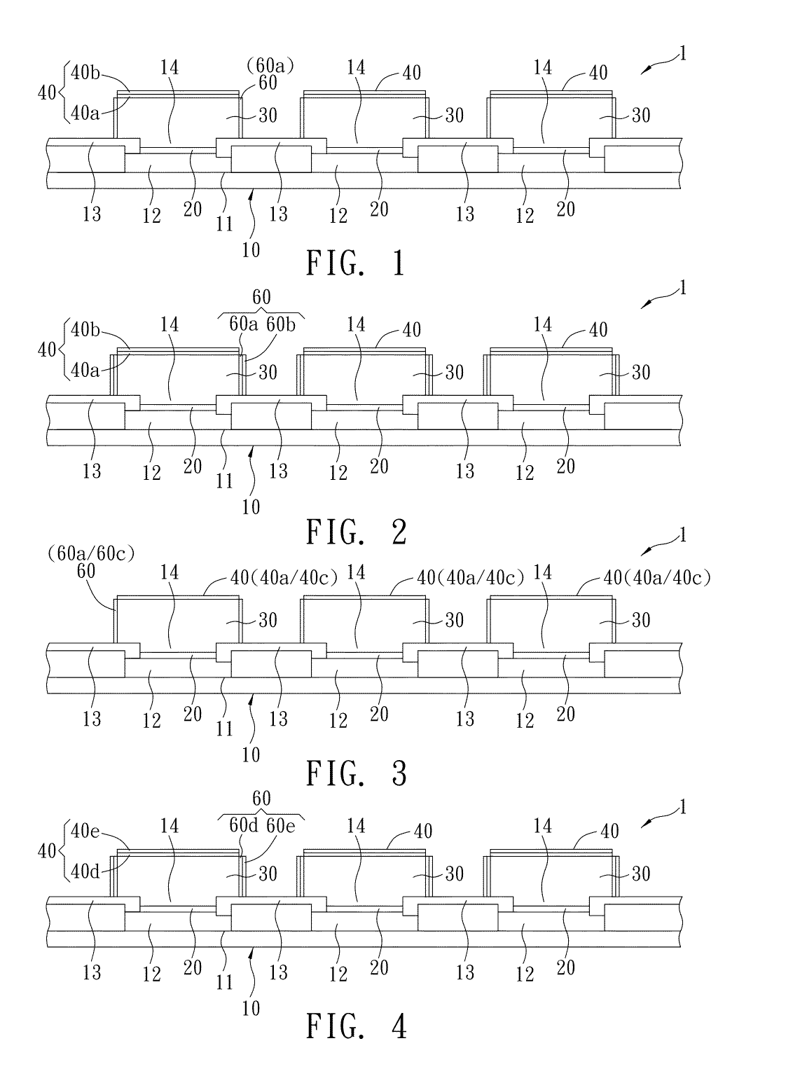

Type one: a double-layer structure formed by an inner immersion gold (IG) layer and an outer electroless gold (EG) layer. The top surface protection layers 40 is formed by an inner IG layer 40a and an outer EG layer 40b, as shown in FIG. 1. The sidewall protection layer 60 consists of an inner IG layer 60a and an outer EG layer 60b, as shown in FIG. 2. First the exposed surface of the electroless nickel bump 30 (such as a top surface and a surrounding sidewall) is coated with an IG layer 40a/60a by immersion gold process. Then an EG layer 40b/60b is formed on an outer surface of the IG layer 40a/60a. In this type, the thickness of the electroless nickel bump 30 is ranging from 2 μm to 14 μm. The thickness of the IG layer 40a/60a is about 0.01-0.05 μm while the thickness of the EG layer 40b/60b is about 0.5-2.0 μm.

Type two: a single-layer structure formed by an immersion gold (IG) layer. Refer to FIG. 3, the top surface protection layers 40 is formed by an IG layer 40a and the sidewall protection layer 60 is formed by an IG layer 60a. The IG layer 40a/60a is formed on the exposed surface of the electroless nickel bump 30 (such as a top surface and a surrounding sidewall) by immersion gold process. In the type two structure, the thickness of the electroless nickel bump 30 is ranging from 2 μm to 14 μm. The thickness of the IG layer 40a/60a is about 0.01 μm to 0.05 μm.

Type three: a single-layer structure formed by an electroless silver (ES) layer. Refer to FIG. 3, the top surface protection layers 40 is formed by an ES layer 40c and the sidewall protection layer 60 is formed by an ES layer 60c. The ES layer 40c/60c is formed on the exposed surface of the electroless nickel bump 30 (such as a top surface and a surrounding sidewall) by immersion silver process. In this structure, the thickness of the electroless nickel bump 30 is ranging from 2 μm to 14 μm. The thickness of the ES layer 40c/60c is about 0.5 μm to 2.0 μm.

Type four: a double-layer structure formed by an inner electroless silver (ES) layer and an outer immersion gold (IG) layer. As shown in FIG. 4, the top surface protection layers 40 is formed by an inner ES layer 40d and an outer IG layer 40e. The sidewall protection layer 60 is composed of an inner ES layer 60d and an outer IG layer 60e. First an ES layer 40d/60d is coated on the exposed surface of the electroless nickel bump 30 (such as a top surface and a surrounding sidewall) by immersion silver process. Then an IG layer 40e/60e is formed on an outer surface of the ES layer 40d/60d. In the type four structure, the thickness of the electroless nickel bump 30 is ranging from 2 μm to 14 μm. The thickness of the ES layer 40d/60d is about 0.5-2.0 μm while the thickness of the IG layer 40e/60e is about 0.01-0.05 μm.

Refer to FIG. 1, the top surface protection layer 40 with the type one structure is used in combination with the sidewall protection layer 60 with the type two structure. Refer to FIG. 2, the top surface protection layer 40 with the type two structure is used together with the sidewall protection layer 60 with the type two structure. As shown in FIG. 3, the top surface protection layer 40 with the type two or type three structure is used in combination with the sidewall protection layer 60 with the type two or type three structure. While the sidewall protection layer 60a (with type two structure) being formed after the formation of the top surface protection layer 40c (with the type three structure) during manufacturing processes, an IG layer may be also formed on the outer surface of the top surface protection layer 40c so as to form the type four structure (not shown in FIG. 3). The top surface protection layer 40 still achieves the expected functions. Refer to FIG. 4, the top surface protection layer 40 with the type four structure is used in combination with the sidewall protection layer 60 with the type four structure.

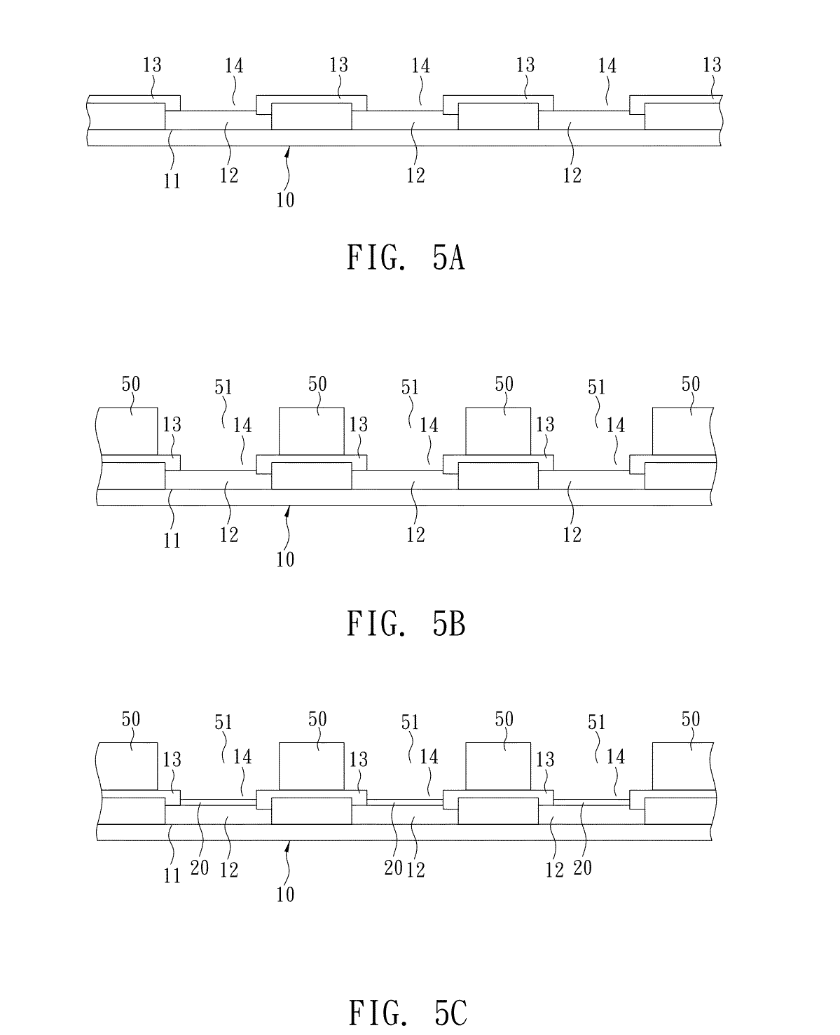

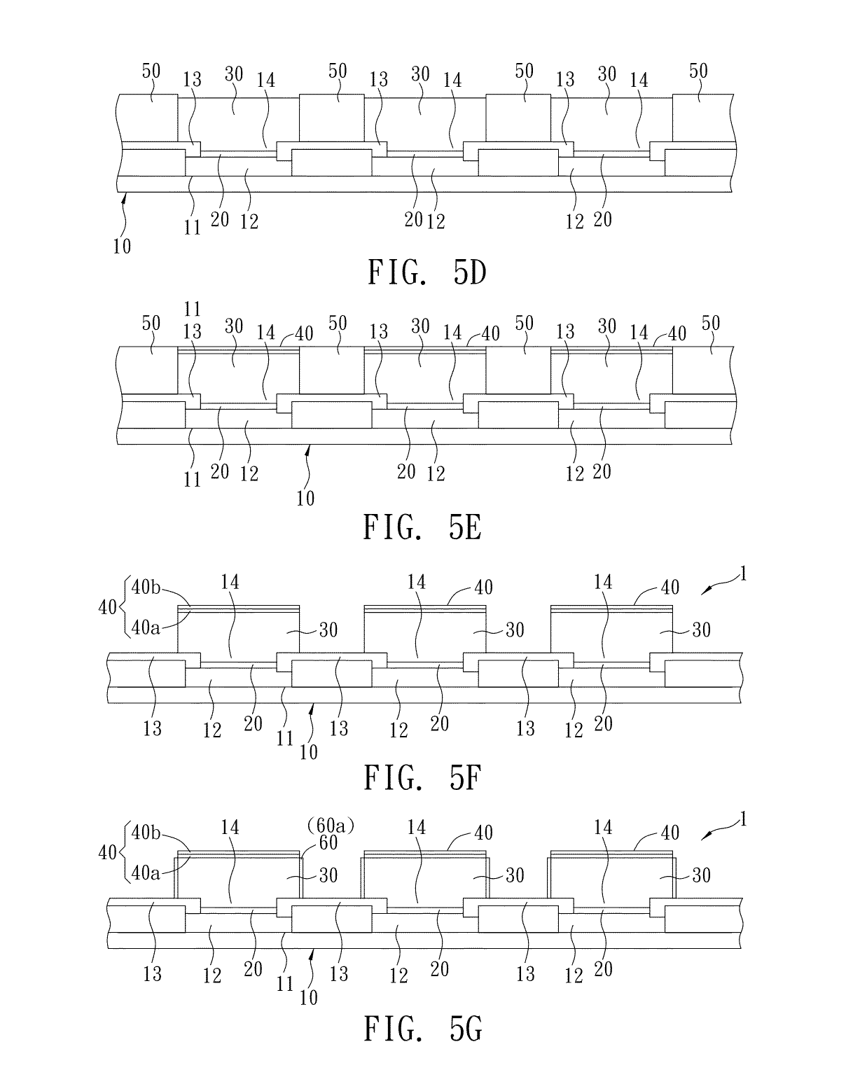

Refer from FIG. 5A to FIG. 5G, a manufacturing method of electroless nickel bumps of die pads includes a plurality of steps as follows.

Refer to FIG. 5A, provide a die 10 with a surface 11. A plurality of die pads 12 is disposed on the surface and a first protection layer 13 with a plurality of openings 14 is formed on the surface 11. The opening 14 is used for exposure of the die pad 12 correspondingly. The distance between the adjacent openings 14 is no more than 16 μm (μm=10⁻⁶ m).

Refer to FIG. 5B, form a photoresist layer 50 on the first protection layer 13 and pattern the photoresist layer 50 so as to make the patterned photoresist layer 50 have a plurality of openings 51 corresponding to each die pad 12 and a part of the first protection layer 13 surrounding the die pad 12.

Refer to FIG. 5C, form a catalyst layer 20 on a surface of each die pad 12 by a process selected from the group consisting of under bump metallization (UBM) and zincating. In an embodiment, the catalyst layer 20 made from zinc is produced by using 15-30% (w/w) aqueous solutions of zinc salts at 20-35 degrees Celsius for 10 seconds to 60 seconds.

Refer to FIG. 5D, form an electroless nickel bump 30 in each of the openings 51 by electroless nickel plating. In this embodiment, the thickness of the electroless nickel bump 30 is no less than 6 μm (the thickness ≧6 μm). In this embodiment, the electroless nickel bump 30 is formed under the condition arranged with the patterned photoresist layer 50. The height of the electroless nickel bump 30 formed in this embodiment is generally larger than the height of the bump formed under the condition without the arrangement of the photoresist layer 50. In this embodiment, the electroless nickel bump 30 is produced by deposition of 4-6.5 g/L aqueous solutions of nickel salts at 75-100° C. for 30 minutes to 75 minutes. The thickness of the electroless nickel bump 30 is 2-15 μm.

Refer to FIG. 5E, under the condition arranged with the patterned photoresist layer 50 shown in FIG. 5D, form a top surface protection layer 40 on a top surface of each electroless nickel bump 30 by a process selected from the group consisting of immersion gold and immersion silver. The top surface protection layer 40 includes at least one protection layer, as 40a, 40b shown in FIG. 1 and FIG. 2, 40a/40c in FIG. 3, or 40d, 40e shown in FIG. 4. The top surface protection layer 40 is made from a material selected from the group consisting of immersion gold (IG) and electroless silver (ES). The top surface protection layer 40 can be one of the four types structure mentioned above such as the type one structure (40a, 40b) shown in FIG. 1 and FIG. 2, the type two or the type three structure (40a/40c) in FIG. 3 or the type four structure (40d, 40e) shown in FIG. 4. In the embodiment shown in FIG. 5E and FIG. 5F, the top surface protection layer 40 is having the type one structure shown in FIG. 1 and FIG. 2.

Refer to FIG. 5F, remove the photoresist layer 50 to expose the top surface protection layers 40, the electroless nickel bumps 30 and a part of the first protection layers 13 not beyond the bumps 30.

Refer to FIG. 5G, form a sidewall protection layer 60 on a surrounding sidewall of each electroless nickel bump 30 by a process sleeted from the group of immersion gold and immersion silver. Thus the manufacturing of the electroless nickel bumps of die pads 1 has been completed. The sidewall protection layer 60 includes at least one protection layer as 60a shown in FIG. 1, 60a, 60b in FIG. 2, 60c in FIG. 3, or 60d, 60e shown in FIG. 4. The sidewall protection layer 60 is made from a material selected from the group consisting of immersion gold (IG) and electroless silver (ES). The sidewall protection layer 60 can be one of the four types structure mentioned above such as the type two structure (60a) shown in FIG. 1, the type one structure (60a, 60b) shown in FIG. 2, the type three structure (60c) in FIG. 3 or the type four structure (60d, 60e) shown in FIG. 4. In the embodiment shown in FIG. 5G, the sidewall protection layer 60 is having the type two structure shown in FIG. 1.

In the embodiment shown from FIG. 5A to FIG. 5G, the top surface protection layers 40 and the sidewall protection layers 60 are produced by two separated processes. First top surface protection layers 40 are formed on top surface of the electroless nickel bumps 30 by a process selected from the group consisting of immersion gold and immersion silver. Then a sidewall protection layer 60 is formed on a surrounding sidewall of each electroless nickel bump 30 by a process selected from the group consisting of immersion gold and immersion silver after removing the photoresist layer 50 (as shown in FIG. 5F). Due to the separated processes, the structure type of the sidewall protection layers 60 can be different from that of the top surface protection layers 40, as shown in FIG. 1. In this embodiment, the sidewall protection layer 60 is having type two structure—a single-layer structure formed by an immersion gold (IG) layer. Thus the cost is down and this doesn't affect the quality of the electroless nickel bumps of the die pads of the present invention.

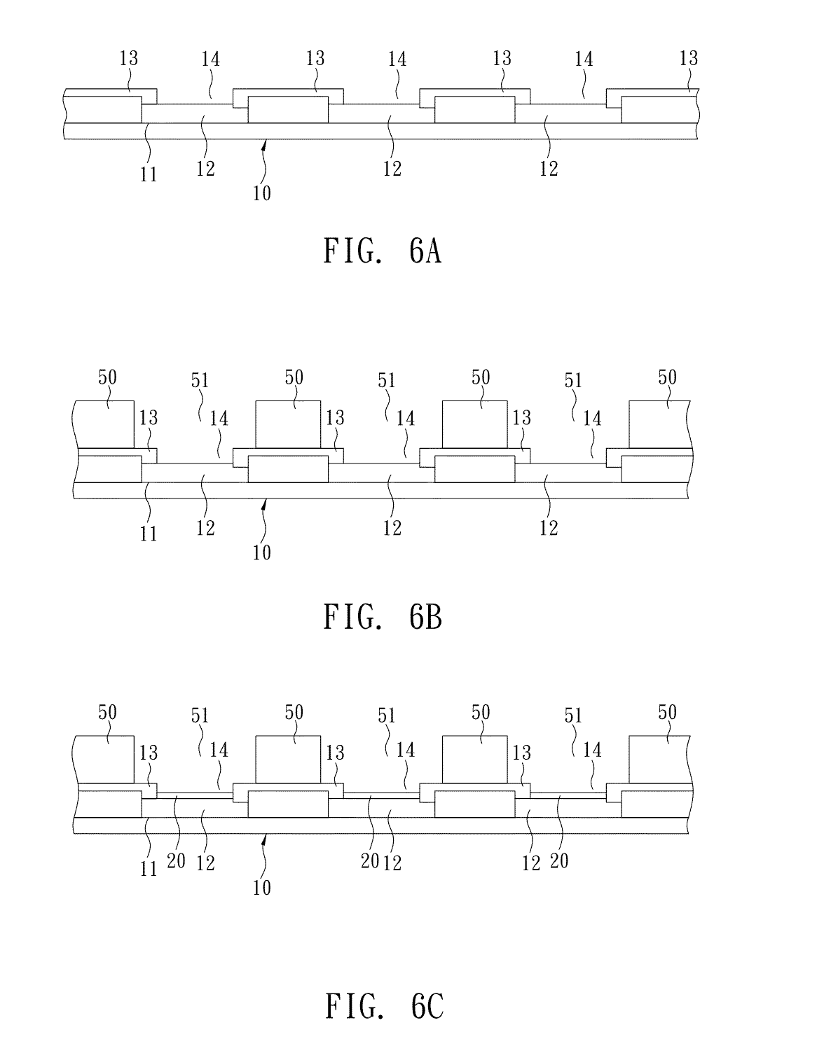

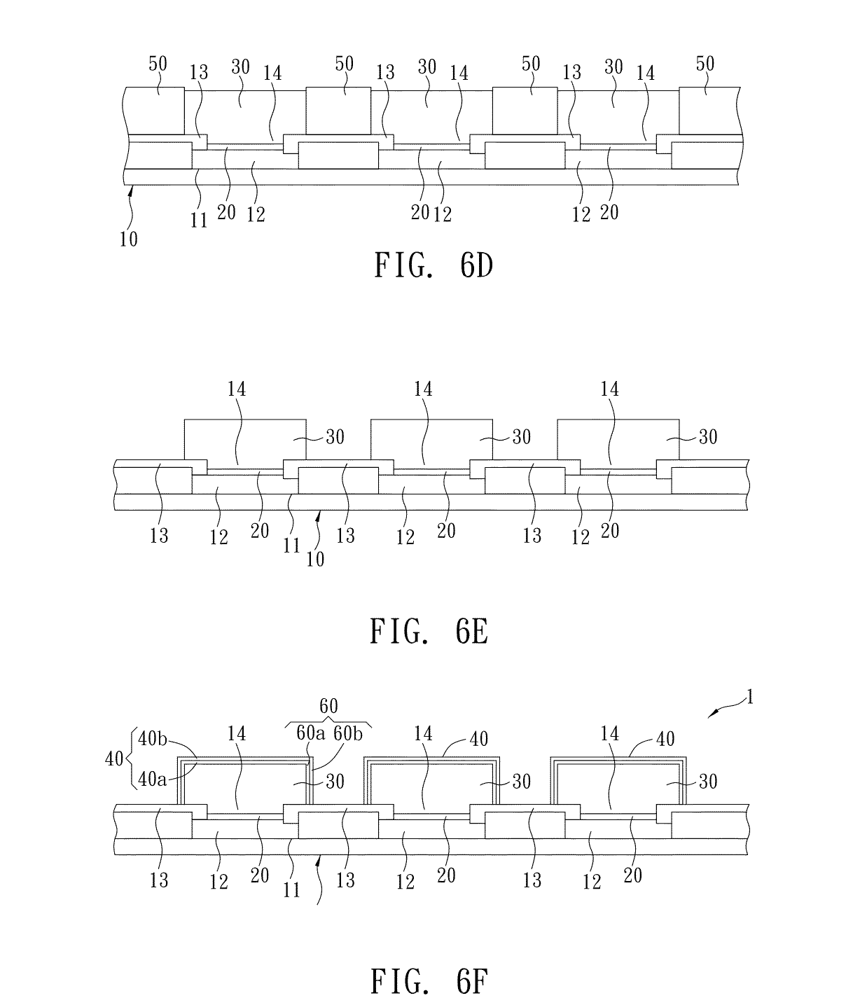

Moreover, refer from FIG. 6A to FIG. 6F, another embodiment of a manufacturing method of electroless nickel bumps of die pads is revealed. The method includes a plurality of steps as follows.

In this embodiment, step 6A, step 6B, step 6C and step 6D are the same as the step 5A, step 5B, step 5C and step 5D of the above embodiment.

Refer to FIG. 6E, remove the photoresist layer 50 to expose the electroless nickel bumps 30 including the top surface and the surrounding sidewall thereof, and a part of the first protection layers 13 not beyond the bumps 30.

Refer to FIG. 6F, form an outer protection layer 40, 60 on a top surface and a surrounding sidewall of each electroless nickel bump 30 respectively at the same time by a process selected from the group of immersion gold and immersion silver. The top surface protection layer 40 on the top surface of each electroless nickel bump 30 and the sidewall protection layer 60 on the surrounding sidewall of each electroless nickel bump 30 are covered over the exposed surface of each electroless nickel bump 30 completely and tightly so as to form an integrated protection layer. Each outer protection layer 40, 60 includes at least one protection layer made from one material selected from immersion gold and electroless silver.

In the embodiment shown from FIG. 6A to FIG. 6F, the top surface protection layers 40 and the sidewall protection layers 60 are produced by the same process. That means they are formed on the exposed stop surface and the exposed surrounding sidewall of the electroless nickel bumps 30 by a process selected from the group consisting of immersion gold and immersion silver at the same time. Thus the structure type of the sidewall protection layers 60 is the same as that of the top surface protection layers 40, as shown in FIG. 2, FIG. 3, and FIG. 4. While the top surface protection layers 40 are with type one structure—a double-layer structure formed by an inner immersion gold (IG) layer and an outer electroless gold (EG) layer. Compared with the embodiment in FIG. 1, these embodiments have higher cost for materials. But this doesn't affect the quality of the electroless nickel bumps of the die pads of the present invention.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

1. Electroless nickel bumps of die pads comprising:
a die having a surface, a plurality of die pads disposed on the surface, and a protection layer that is formed on the surface and having a plurality of openings, wherein the die pad is exposed through the opening correspondingly;
a plurality of catalyst layers that is formed on the surface of the die pads respectively by under bump metallization (UBM) or zincating;
a plurality of electroless nickel bumps with a certain height that is made from electroless nickel and formed on surface of the catalyst layers on surface of the die pads by electroless nickel plating under a condition with photoresist coating;
a plurality of top surface protection layers that are formed on a top surface of the electroless nickel bumps respectively by a process selected from the group consisting of immersion gold and immersion silver, wherein each of the top surface protection layers having at least one protection layer is made from a material selected from the group consisting of immersion gold or electroless silver; and
a plurality of sidewall protection layers that are formed on a surrounding sidewall of the electroless nickel bumps respectively by a process selected from the group consisting of immersion gold and immersion silver, each of the sidewall protection layers having at least one protection layer made from a material selected from the group consisting of immersion gold or electroless silver;
wherein the top surface protection layer on the top surface of the electroless nickel bump and the sidewall protection layer on the surrounding sidewall of the electroless nickel bump are covered over the surface of the electroless nickel bump completely and tightly so as to form an integrated protection layer.

2. The device as claimed in claim 1, wherein the top surface protection layers and the sidewall protection layers are formed by two separated processes, the top surface protection layers are first formed on the top surface of the electroless nickel bumps by a process selected from the group consisting of immersion gold and immersion silver, and then sidewall protection layers are formed on the surrounding sidewall of the electroless nickel bumps respectively by a process selected from the group consisting of immersion gold and immersion silver.

3. The device as claimed in claim 2, wherein the structure of each of the top surface protection layers formed on top surface of the electroless nickel bumps respectively is selected from the group consisting of a single-layer structure formed by an immersion gold (IG) layer, a double-layer structure formed by an inner immersion gold (IG) layer and an outer electroless gold (EG) layer, a single-layer structure formed by an electroless silver (ES) layer, and a double-layer structure formed by an inner electroless silver (ES) layer and an outer immersion gold (IG) layer.

4. The device as claimed in claim 3, wherein the structure of each of the sidewall protection layers formed on the surrounding sidewall of the electroless nickel bumps respectively is selected from the group consisting of a single-layer structure formed by an immersion gold (IG) layer, a double-layer structure formed by an inner immersion gold (IG) layer and an outer electroless gold (EG) layer, a single-layer structure formed by an electroless silver (ES) layer, and a double-layer structure formed by an inner electroless silver (ES) layer and an outer immersion gold (IG) layer.

5. The device as claimed in claim 3, wherein the double-layer structure formed by an inner immersion gold (IG) layer and an outer electroless gold (EG) layer is produced by an IG layer first formed on a surface of the electroless nickel bump and then an EG layer formed on an outer surface of the IG layer, and the IG layer and the EG layer are formed by an immersion gold process.

6. The device as claimed in claim 3, wherein the double-layer structure formed by an inner electroless silver (ES) layer and an outer immersion gold (IG) layer is produced by an ES layer first formed on a surface of the electroless nickel bump and then an IG layer formed on an outer surface of the ES layer, the ES layer is formed by an immersion silver process, and the IG layer is formed by an immersion gold process.

7. The device as claimed in claim 3, wherein the thickness of the electroless nickel bump is about 2-14 μm, the thickness of the IG layer is about 0.01-0.05 μm, the thickness of the EG layer is about 0.5-2.0 μm, and the thickness of the ES layer is about 0.5-2.0 μm.

8. The device as claimed in claim 1, wherein the top surface protection layers and the sidewall protection layers are made by the same process, and the top surface protection layers and the sidewall protection layers are formed on the top surface and the surrounding sidewall of the electroless nickel bumps respectively at the same time by a process selected from the group consisting of immersion gold and immersion silver.

9. The device as claimed in claim 8, wherein the top surface protection layers formed on the top surface of the electroless nickel bumps and the sidewall protection layers formed on the top surface of the electroless nickel bumps have a structure selected from the group consisting of a single-layer structure formed by an immersion gold (IG) layer, a double-layer structure formed by an inner immersion gold (IG) layer and an outer electroless gold (EG) layer, a single-layer structure formed by an electroless silver (ES) layer, and a double-layer structure formed by an inner electroless silver (ES) layer and an outer immersion gold (IG) layer.

10. The device as claimed in claim 8, wherein the double-layer structure formed by an inner immersion gold (IG) layer and an outer electroless gold (EG) layer is produced by an IG layer first formed on a surface of the electroless nickel bump and then an EG layer formed on an outer surface of the IG layer, and the IG layer and the EG layer are formed by an immersion gold process.

11. The device as claimed in claim 8, wherein the double-layer structure formed by an inner electroless silver (ES) layer and an outer immersion gold (IG) layer is produced by an ES layer first formed on a surface of the electroless nickel bump and then an IG layer formed on an outer surface of the ES layer, the ES layer is formed by an immersion silver process, and the IG layer is formed by an immersion gold process.

12. The device as claimed in claim 9, wherein the thickness of the electroless nickel bump is about 2 μm to 14 μm, the thickness of the IG layer is about 0.01 μm to 0.05 μm, the thickness of the EG layer is about 0.5 μm to 2.0 μm and the thickness of the ES layer is about 0.5 μm to 2.0 μm.

13. A manufacturing method of electroless nickel bumps of die pads comprising the steps of:
providing a die with a surface while a plurality of die pads is disposed on the surface and a first protection layer with a plurality of openings for exposure of the die pads are correspondingly formed on the surface;
forming a photoresist layer on the first protection layer and patterning the photoresist layer so as to form a plurality of openings on the photoresist layer corresponding to each of the die pads and a part of the first protection layer surrounding the die pad;
forming a catalyst layer on the surface of each of the die pads by a process selected from the group consisting of under bump metallization (UBM) and zincating;
forming an electroless nickel bump in each of the openings by electroless nickel plating;
forming a top surface protection layer on the top surface of the electroless nickel bump by a process selected from the group consisting of immersion gold and immersion silver under a condition with the photoresist layer while the top sufacc surface protection layer includes at least one protection layer made from a material selected from the group consisting of immersion gold (IG) and electroless silver (ES);
removing the photoresist layer to expose the electroless nickel bumps, the top surface protection layers, and a part of the first protection layers not beyond the bumps; and
forming a sidewall protection layer on a surrounding sidewall of each of the electroless nickel bumps by a process selected from the group consisting of immersion gold and immersion silver while the sidewall surface protection layer includes at least one protection layer made from a material selected from the group consisting of immersion gold (IG) and electroless silver (ES).

14. A manufacturing method of electroless nickel bumps of die pads comprising the steps of:
providing a die with a surface while a plurality of die pads are disposed on the surface and a first protection layer with a plurality of openings for exposure of the die pads are correspondingly formed on the surface;
forming a photoresist layer on the first protection layer and patterning the photoresist layer so as to form a plurality of openings on the photoresist layer corresponding to each of the die pads and a part of the first protection layer surrounding the die pad;
forming a catalyst layer on a surface of each of the die pads by a process selected from the group consisting of under bump metallization (UBM) and zincating;
forming an electroless nickel bump in each of the openings by electroless nickel plating;
removing the photoresist layer to expose the electroless nickel bumps, and a part of the first protection layer not beyond the bumps; and
forming an outer protection layer on a top surface and a surrounding sidewall of each of the electroless nickel bumps respectively at the same time by a process selected from the group consisting of immersion gold and immersion silver, the outer protection layer includes at least one protection layer made from a material selected from the group consisting of immersion gold (IG) and electroless silver (ES).

15. The device as claimed in claim 4, wherein the double-layer structure formed by an inner immersion gold (IG) layer and an outer electroless gold (EG) layer is produced by an IG layer first formed on the surface of the electroless nickel bump and then an EG layer formed on the outer surface of the IG layer, and the IG layer and the EG layer are formed by an immersion gold process.

16. The device as claimed in claim 4, wherein the double-layer structure formed by an inner electroless silver (ES) layer and an outer immersion gold (IG) layer is produced by an ES layer first formed on the surface of the electroless nickel bump and then an IG layer formed on an outer surface of the ES layer, the ES layer is formed by an immersion silver process, and the IG layer is formed by an immersion gold process.

17. The device as claimed in claim 4, wherein the thickness of the electroless nickel bump is about 2-14 μm, the thickness of the IG layer is about 0.01-0.05 μm, the thickness of the EG layer is about 0.5-2.0 μm, and the thickness of the ES layer is about 0.5-2.0 μm.
